(19) United States
(12) Patent Application Publication
(10) Pub. No.: US 2015/0076189 A1
(43) Pub. Date: Mar. 19, 2015

(54) Housing for an electronic device

(71) Applicant: Dwight Gilbert Jones, North Vancouver (CA)

(72) Inventor: Dwight Gilbert Jones, North Vancouver (CA)

(21) Appl. No.: 14/031,286

(22) Filed: Sep. 19, 2013

(51) Int. Cl. H05K 5/02; A45C 11/00

(52) U.S. Cl. CPC H05K 5/0247; A45C 11/00; A45C 2011/001; A45C 2011/003
USPC 224/191

(57) ABSTRACT

This disclosure relates generally to an apparatus for housing electronic devices. It introduces a modular form factor for utilizing tablet computers as components within fixed computer terminals. The one-piece housing is surface mounted, and is flared toward one end, assisting sound emanation as an acoustic horn, with its viewing face angled. The tablet is affixed within, with its screen viewable through the housing's wide window aperture, and its manual controls remain accessible through the open bottom. The housing can completely surround a standard power outlet above counter tops, for protection and to minimize and conceal associated cabling. Components are largely fastened and assembled into the device using industrial mounting tape. The housing's voluminous interior can accommodate additional modular components such as a power distribution hub, speakers and other electronic devices.

### CROSS-REFERENCE TO RELATED APPLICATIONS

Provisional application No. 61/744,228 filed Sep. 21, 2012

### STATEMENT REGARDING FEDERALLY SPONSORED RESEARCH OR DEVELOPMENT

Not applicable

### REFERENCE TO SEQUENCE LISTING, A TABLE, OR A COMPUTER PROGRAM LISTING COMPACT DISC APPENDIX

Not applicable

### BACKGROUND OF THE INVENTION

This invention relates to housings such as those described in USPC 361/679.02 “computer related housing or mounting assemblies”. Its development followed inquiries seeking a way to detect when people accessed AEDs (Automated External Defibrillators) while opening the AED enclosure. A means was sought for sending a message or alarm arising from the lid being opened, which would activate an M2M (machine-to-machine) modem operating on a wireless network. Eventually it became evident that a tablet computer incorporated all of the communications functions required, as well as having global positioning and accelerometer functions that could also be exploited. It was decided at first to embed a tablet within the lid of such enclosures, and to utilize existing industrial instrument boxes. However, the expense and complex manufacturing required of a custom lid for commercially available enclosures resulted in a rethinking of this approach.

It was realized that a tablet within a mountable lid could also be affixed to a wall, by itself and on its own merits, and serve as a computer terminal, especially over counter tops and in work areas.

If it surrounded a household 110/220V power outlet, then its power connection was contained therein, and any cabling was minimized, protected and aesthetically concealed. Small portable speakers could be tucked within it, as well as a USB 5W power distribution hub, and in that way the integrated unit could operate using just one of the power plugs, at very low power, and leave the second one available for other appliances or uses.

The tablet and its enclosure could also be utilized as a terminal if simply laid flat on a work surface, for data entry or email accessing, as examples, with its screen face angled toward the user and its bottom end pointed away from them, optionally with a speaker bar contained within it to support a full audio/video experience.

A design was produced which described a housing or casing which could be cast or injection-molded as one piece, with an inclined window in its face for viewing the internal tablet. By leaving the bottom of the housing open, the tablet's volume and power controls could be accessed directly by hand, and the second power point in a standard outlet remained accessible for an appliance like a toaster to plug into.

By utilizing industrial two-sided tape, non-destructive assembly and mounting avoided drilling holes in expensive backsplashes or work surfaces, and hangers made from extruded aluminum were easily attached for wall mounting.

Finally, the housing was scaled to accept the common ten inch class of tablets, offering the viewing ease of a small Internet television, with enough internal space remaining to secure a compact AED within the housing.

### BRIEF SUMMARY OF THE INVENTION

The resulting housing is a modular solution that can re-purpose tablets to function as fixed video and audio terminals, or Internet televisions and to enclose consumer and industrial electronics, as a new form factor derived from a single casting configuration.

### BRIEF DESCRIPTION OF THE SEVERAL VIEWS OF THE DRAWING

FIG. 1 is a perspective view of the electronic device housing.

FIG. 2 is a side elevation view of the electronic device housing (mirrored other side).

FIG. 3 is a top view of the electronic device housing.

FIG. 4 is a rear elevation view of the electronic device housing.

### DETAILED DESCRIPTION OF THE INVENTION

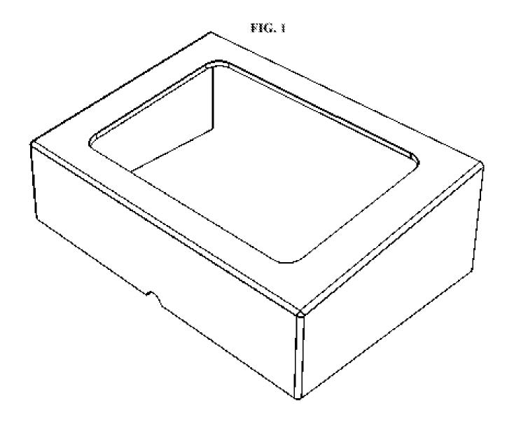

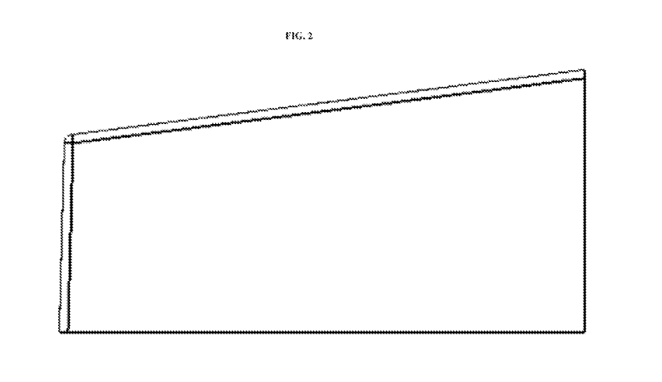

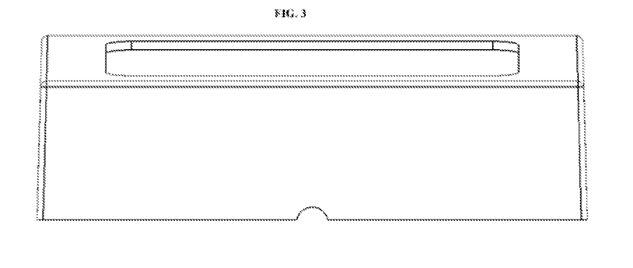

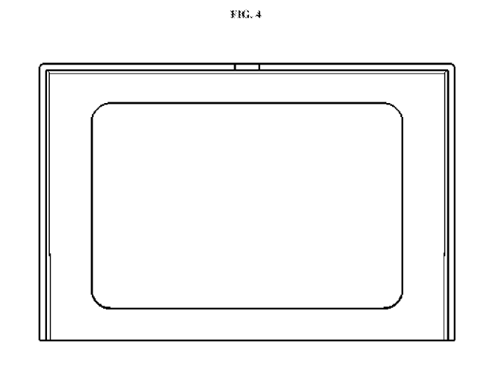

Referring to drawings FIG. 1-4, an exemplary embodiment of the invention is illustrated. The invention relies on geometric design and manual access to interior components and their controls to enable its functions and advantages.

Being modular, its sizing or scale can be matched to almost any tablet computer size, ranging from small tablets usable as gauges and control units, without audio, to large tablets that offer a maximum video viewing area, with optional audio output devices either wired or wireless. For bare tablets alone within it, the housing acts as an acoustic horn for sound emanating from its open bottom.

The use of industrial mounting tape allows installations to be removable without leaving holes in high value surfaces such as kitchen backsplashes, desk and table tops, stainless steel work counters, or mirrors—all of which can readily be utilized as suitable sites for locating the device.

Hard, non-porous materials are difficult to drill into for assembly and mounting, and to later repair, but they are ideal for organizing and securing devices with industrial mounting tape. The consumer electronics industry has had difficulty penetrating kitchen markets, as an example, because wall-mounting their devices would be destructive, with the resulting cable clutter both dangerous and unsightly. This invention addresses each of those issues.

The housing can be fabricated individually by multiple techniques using various materials. An early prototype cited in the provisional application was made from balsa wood. It is conceivable that wood and the artistic warmth it promises will prove to be popular and completely functional. A wooden version can be finished and painted to please the owner or artist; it can be carved and individualized in many ways.

In the fully modern environment, the device can be 3D printed or made using a CNC milling machine, for one-off units or short production runs.

For low-volume industrial manufacturing, production in sand cast aluminum at a foundry is appropriate. A pattern maker prepares a “loose” pattern for individual castings, or perhaps a “2-Up plate” for use within an automated casting machine. The resulting product leverages the relatively low weight and cost of aluminum metal and this design's absence of “undercuts”, which could obstruct or preclude extraction from the mold.

The drawings FIG. 1-4 illustrate such a mold pattern for producing the housing at a foundry. The material can be 356 aluminum, with dimensions of 12″×8″×4″ with a 9″×6″ window opening for the tablet screen.

After cooling, the sand casting is machined smooth on its exterior surfaces, which are bare of artwork to facilitate this. The housing is then powder painted to an enamel-like finish, and optionally silkscreened with any desired printing or logo.

For high volume manufacturing, plastic injection molding is appropriate, requiring a more expensive steel mold, but resulting in a low per-piece cost about 80% less than with sand casting. The plastic of choice is usually ABS and the design admits of some artwork across its surfaces if desired.

High quality industrial production in volume is best achieved with die casting in metal such as aluminum or zinc, with a higher level of finish and design complexity possible. The cost for the mold is high for die casting, typically requiring expensive H13 steel, but the piece price is perhaps only twice that of plastic, and the die cast metal product, once finished, has a superior appearance.

This invention describes basic castings of the housing that fully realize all functions. Tolerances are generous, as the housing does not mesh with other parts except via tape or gaskets. The cast metal product is reassuringly heavy and rigid—ideal for resisting the constant physical poking of touch computing. The enameled finish supports its identity as a fixed terminal “appliance” that is easily cleaned, thus maintaining its clean, bright appearance indefinitely.

Sand casting done as a simple copy of an existing unit, in the developing world could facilitate easy production there, in low-tech shops. Tablets typically draw less than 10W of electricity, as do the supporting USB and Bluetooth devices, so these aggregate terminals are ideal as web access points in solar power environments and communities. An older tablet can be re-purposed at very low cost to become a family education and entertainment portal using communal bandwidth.

An economical method of attaching the housing and its other components, to each other and to the wall or work surface, is by using off-the-shelf extruded aluminum hangers and industrial mounting tape, with both available in various sizes and lengths at hardware suppliers.

In a typical installation, an aluminum extruded Z-shaped molding is taped or screwed to the wall immediately above the power outlet, in a typical kitchen, bathroom, or work area over the countertop. The hanger length is about 10% less than the width of the device itself to allow easy removal and guided re-hanging. The housing can then have a matching length of 90° molding taped to its upper edge, that drops into the Z molding on the wall, and the hanging is secured with adequate strength when industrial-grade tape is used.

This Z molding can be biased toward one side or the other of the wall power outlet by approximately one third of its length, to optimize the horizontal positioning of the terminal to envelope its internal components, or simply to line up better with its counter top surroundings. The housing can thus be lifted out, disconnected and put back up as required, although this procedure is intended to be a configuring or maintenance convenience, not a frequent routine. During assembly, the tablet can simply be laid onto the window aperture, aligned, and then taped along open stretches of its outer perimeter directly to the inner housing, leaving the exposed side of the tape un-stripped. Subsequently the tablet can readily be extracted by first cutting along these taped seams with a knife edge.

For more security, the housing itself can be taped along its internal, lower edges to the mounting surface, which then strongly resists its removal. This extra taping can also control vibration or rattling if it occurs.

The tablet and any speakers should remain charged while in use, and the tablet can be rebooted manually via the open bottom's access to the tablet's power button, which is oriented during assembly to be accessible. An internal multiport power hub charges the housing's components continuously, and potentially also cellphones placed on its top ledge, which has a half-moon opening for wiring egress.

The integrated terminal thus minimizes, protects and conceals component cabling, and only the elegant bare instrument presents itself, since the speakers can usually be tucked inside the open bottom. When the video and audio are active this is a distinctive and appealing instrument. Kitchen and work area terminals have faced barriers for mounting them, for the attending ugliness and danger of cable clutter, and the loss of valued counter space and power plugs. This invention resolves these issues with a very low power, wireless modular solution that re-purposes tablets as terminal components, while introducing a versatile and economical new computing form factor.

1. A housing for electronic devices has a flared casing and open end.

2. A wall housing for electronic devices has a flared casing and open bottom.
A wall housing in accordance with claim 2, wherein the housing contains a tablet computer
A wall housing in accordance with claim 2, wherein the housing contains a tablet viewing window
A wall housing in accordance with claim 2, wherein the housing contains an audio speaker device.
A wall housing in accordance with claim 2, wherein the housing contains an electrical power distribution device.
A wall housing in accordance with claim 2, which completely surrounds a household electrical power outlet.
A wall housing in accordance with claim 2, which minimizes, protects and conceals associated electrical cables.
A wall housing in accordance with claim 2, which is fabricated as a single piece.
